(19) United States
(12) Patent Application Publication
(10) Pub. No.: US 2012/0020073 A1
(43) Pub. Date: Jan. 26, 2012

(54) OPTICALLY PUMPED SOLID-STATE LASER AND LIGHTING SYSTEM COMPRISING SAID SOLID-STATE LASER

(75) Inventors: Ulrich Weichmann, Aachen (DE); Cornelis Reinder Ronda, Aachen (DE); Joachim Opitz, Aachen (DE); Peter Josef Schmidt, Aachen (DE)

(73) Assignee: KONINKLIJKE PHILIPS ELECTRONICS N.V., Eindhoven (NL)

(21) Appl. No.: 13/258,618

(22) PCT Filed: Mar. 15, 2010
(86) PCT No.: PCT/IB2010/051092

§ 371 Date: Sep. 22, 2011

(30) Foreign Application Priority Data
Mar. 23, 2009 (EP) 09155913.8

(51) Int. Cl. F21V 9/00; H01S 5/02

(52) U.S. Cl. 362/231; 372/43.01

(57) ABSTRACT

The invention relates to a solid-state laser device (1) comprising a gain medium (10) essentially having a main phase of a solid state host material (15) which is doped with rare-earth ions. According to the invention at least a portion of the rare-earth ions are Ce³⁺-ions (19) with at least one 4f-state (16, 17) and at least one 5d-band (18) energetically between the highest valence state and the lowest conduction state of the host material (15), wherein
the highest 4f-state (17) and the bottom edge of the 5d-band (18) have a first energy-level distance (Δ1) and
the lowest 4f-state (16) and the upper edge of the 5d-band (18) have a second energy-level distance (Δ2),
wherein the host material (15) is selected such that the resulting gain medium (10) has an energy range (20) devoid of unoccupied states for disabling excited state absorption, the energy range (20) is located between
a lower energy (21) which is by the value of the first energy level distance (Δ1) above the bottom edge of the 5d-band (18) and
a higher energy (22) which is by the value of the second energy level distance (Δ2) above the upper edge of the 5d-band (18).

The invention further relates to a corresponding lighting system comprising at least one solid-state laser device (1).

### FIELD OF THE INVENTION

The present invention relates to a solid-state laser device comprising a gain medium essentially having a main phase of a solid state host material which is doped with rare-earth ions. The present invention further relates to a corresponding lighting system comprising at least one of said solid-state laser devices.

### BACKGROUND OF THE INVENTION

Lasers will replace UHP-lamps (UHP: Ultra High Performance) as light sources for projection systems and other systems requiring high luminance light sources. While red and blue laser diodes are available, the lack of integrated laser sources in the wavelength region of green light has—until now—blocked the widespread use of lasers for display applications or illumination applications. Until now, integrated green lasers are not available and wavelength conversion schemes have to be applied.

Blue diode pumped solid-state lasers (bDPSSL) based on Pr³⁺-doped fluoride materials as gain medium have recently attracted a lot of interest for such an integrated green laser. These lasers are limited to wavelength selected and stabilized pump-diodes. They employ a linear wavelength conversion scheme. This results in a lower sensitivity to temperature drifts than second-harmonic systems and the potential to become an integrated and therefore low-cost solution. A typical setup of such a blue diode pumped solid-state laser based on Pr³⁺-doped fluoride materials uses Pr:YLF (YLF: yttrium lithium fluoride) as laser gain medium (lasing medium).

These lasers reach quite high efficiencies but have at the same time several drawbacks and disadvantages with respect to applications such as integrated projection: Pr:YLF has a narrow absorption line at the emission wavelength of typical blue laser diodes (˜445 nm). This requires the selection of laser diodes that have an emission spectrum accurately matching the Pr-absorption. Such a binning and selection of laser diodes will directly increase the cost of the pump laser and the total system. Furthermore, the emission of the laser diodes shifts with diode current and temperature.

Cerium doped Yttrium aluminum garnet (Ce:YAG) has found widespread use as a phosphor in light emitting diodes (LEDs). Unlike the optical transitions in Pr³⁺-ions in the visible range that are electric dipole-forbidden transitions between different 4f-states, the relevant transitions in Ce³⁺-ions are between 4f- and 5d-levels and electric dipole-allowed. In YAG:Ce this results in a strong and broad absorption in the blue wavelength region and a broad and strong emission band that stretches from 500 to 650 nm, with the maximum at yellow wavelengths.

Due to these advantageous features, Ce:YAG was also investigated as a material for solid-state lasers. However, strong absorption from the anticipated upper laser level to the conduction band or another high-lying 5d-level of the Ce-ion prevents lasing in this material. This absorption phenomenon is called excited state absorption (ESA). The same situation is given in Ce:Lu₃Al₅O₁₂ (Ce:LuAG). In Ce:Lu₃Al₅O₁₂ the ESA-process ends at an energetic position, where the excitation spectrum shows a strong signal. This strong signal is an indication for a high density of states at the relevant energy for ESA; therefore ESA prevents laser action in Ce:LuAG.

### SUMMARY OF THE INVENTION

It is an objective of the present invention to provide a solid state laser emitting in the green wavelength region emitting light in a wavelength region from 480 to 580 nm or any sub-region of this wavelength region, which can be pumped by a light emitting device like an LED or a laser diode, emitting at shorter wavelengths.

This objective is achieved with the solid state laser according to claim 1. Advantageous embodiments are subject matter of the sub-claims and/or are described in the subsequent description including the embodiments for carrying out the invention.

The proposed solid state laser comprises a gain medium essentially having a main phase of a solid state host material which is doped with rare-earth ions, wherein at least a portion of the rare-earth ions are Ce³⁺-ions with the 4f-ground-state and at least one 5d-band energetically between the highest valence state and the lowest conduction state of the host material, wherein the highest 4f-state and the bottom edge of the 5d-band have a first energy-level distance and the lowest 4f-state and the upper edge of the 5d-band have a second energy-level distance, wherein the host material is selected such that the resulting gain medium has an energy range devoid of unoccupied states, said energy range disabling excited state absorption (ESA), the energy range is located between a lower energy which is by the value of the first energy level distance above the bottom edge of the 5d-band and a higher energy which is by the value of the second energy level distance above the upper edge of the 5d-band. Preferably the solid state host material is a garnet.

The term “essentially” means especially that ≧95%, preferably ≧98% and most preferred ≧99.5% of the host material of the gain medium has the desired structure and/or composition.

The term “main phase” implies that there may be further phases, e.g. resulting out of mixture(s) of the above-mentioned materials with additives which may be added e.g. during ceramic processing. These additives may be incorporated fully or in part into the final material, which then may also be a composite of several chemically different species and particularly include such species known to the art as fluxes.

A suitable solid state host material can be found by preparing the Ce-doped solid state host material and measuring the optical excitation spectrum and the optical emission spectrum and the photoconductivity spectrum of the resulting gain medium both in the wavelength region from about 150 nm to about 700 nm.

With respect to the present invention, the term “energy range devoid of unoccupied states, said energy range disabling excited state absorption” especially means that the excitation spectrum does not show any observable signal structures within an according spectral energy range corresponding to said unoccupied states.

According to a preferred embodiment of the present invention, the 5d band involved in the lasing process is thermally isolated from the conduction band. The energy difference for thermally isolating the 5d band from the conduction band is at least 0.5 eV.

According to a preferred embodiment of the present invention, the rare-earth ions are Ce³⁺-ions or mixtures of Ce³⁺- and other rare earth-ions, the other rare earth-ions selected from the group of Pr³⁺-, Sm³⁺-, Eu³⁺-, Tb³⁺-, Dy³⁺-, and Tm³⁺-ions.

According to a preferred embodiment of the present invention, the host material is selected from the following materials: (Y_{1-x-y}GdₓLu_{y})₃Al_{5-z}Ga_{z}O₁₂ (1≦z≦5; 0≦x≦1; 0≦y≦1 and x+y≦1). The host material is preferably Y₃AlGa₄O₁₂.

According to another preferred embodiment of the present invention, the host material is selected to be the following material: Ca₃Sc₂Si₃O₁₂. Preferably the solid state host material doped with rare-earth ions is: Ca₃₋ₓCeₓSc₂Si₃O₁₂ (0.005≦x≦0.2); more preferably the solid state host material doped with rare-earth ions is: Ca₂₉₇Ce_{0.03}Sc₂Si₃O₁₂.

According to a preferred embodiment of the present invention, the host material has a dopant concentration of the rare-earth ions in the range of 0.005 mol % to 5 mol %, in particular in the range of 0.1 mol % to 1 mol %.

According to a preferred embodiment of the present invention, the host material is a ceramic or monocrystalline material. The proposed material can be prepared by standard crystal-growth techniques as well as by ceramic sintering techniques. Both methods are quite common for YAG-based laser materials and can easily be transferred to the proposed garnet structure. The possibility for ceramic processing is a further advantage regarding the cost structure of a blue diode pumped solid-state laser (bDPSSL), in comparison to Pr:YLF.

According to a preferred embodiment of the present invention, the solid state laser further comprises a pump light source emitting blue light and/or ultraviolet light, wherein the gain medium is in an optical path of the pump light source. The pump light source preferably is a semiconductor pump diode; in particular a laser diode for pumping the gain medium

According to a preferred embodiment of the present invention, the laser device is a laser device emitting green laser light. The term “green laser light” especially means and/or includes that the gain material shows an emission in the visible range (upon suitable excitation) with a maximum of emission between 480 and 580 nm.

According to a preferred embodiment of the present invention, the laser light emitted by the gain medium is aligned parallel or perpendicular to a main axis of the optical path.

According to a preferred embodiment of the present invention, the host material has an energy gap between the highest valence state and the lowest conduction state of more than 5.5 eV.

The present invention furthermore relates to a lighting system comprising at least one aforementioned solid-state laser device, wherein the system is used in one or more of the following applications:
spot lighting systems,
theater lighting systems,
fiber-optics application systems,
projection systems,
self-lit display systems,
pixelated display systems,
segmented display systems,
warning sign systems,
medical lighting application systems,
indicator sign systems,
portable systems and
automotive applications.

According to a preferred embodiment of the present invention, the laser device of the system is a laser device emitting green laser light.

According to a preferred embodiment of the present invention, the system is a RGB-system (R: red; G: green; B: blue) comprising further laser devices, wherein one of these further laser devices is emitting red light and another of the further laser devices is emitting blue light.

The aforementioned components, as well as the claimed components and the components to be used in accordance with the invention in the described embodiments, are not subject to any special exceptions with respect to their size, shape, material selection and technical concept such that the selection criteria known in the pertinent field can be applied without limitations.

### BRIEF DESCRIPTION OF THE DRAWINGS

Additional details, features, characteristics and advantages of the object of the invention are disclosed in the subclaims, the figures and the following description of the respective figure and examples, which—in an exemplary fashion—show one embodiment and example of a solid-state Laser according to the invention.

In the drawings:

FIG. 1 is a top view of an example of a transversally pumped solid-state laser device according to a preferred embodiment of the invention;

FIG. 2 shows an excitation scheme of a preferred embodiment of the gain medium;

FIG. 3 shows the excitation spectra of different 0.2 mol % Ce-doped garnet materials;

FIG. 4 shows the emission spectrum of 0.2 mol % Ce-doped Y₃AlGa₄O₁₂ (Ce³⁺:Y₃AlGa₄O₁₂) materials; and

FIG. 5 shows the excitation spectrum and the emission spectrum of Ce-doped Ca₃Sc₂Si₃O₁₂ (Ce³⁺: Ca₃Sc₂Si₃O₁₂) materials.

### DETAILED DESCRIPTION OF EMBODIMENTS

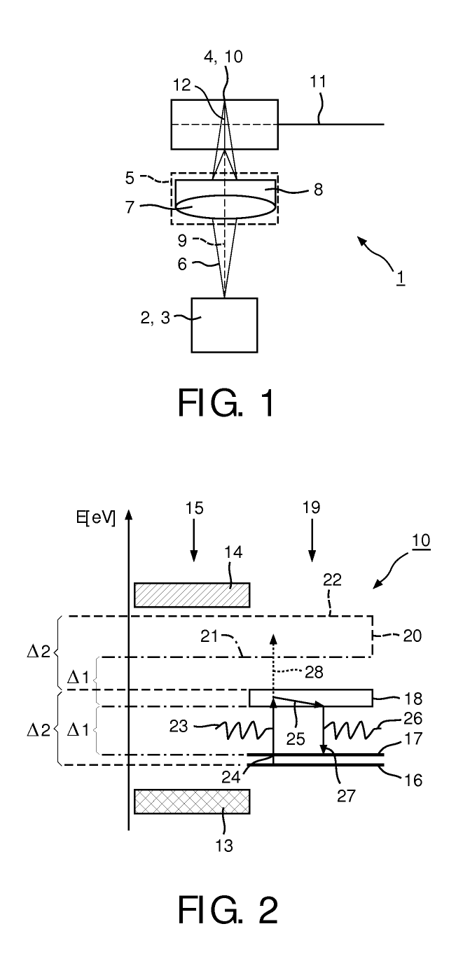

FIG. 1 shows a solid state laser device 1 comprising a pump light source 2 formed as a pump diode 3 emitting light (laser light) in a wavelength region from 360-480 nm. The solid state laser device 1 further comprises a gain device 4 and an optical device 5. The gain device 4 and the optical device 5 are arranged in an optical path 6 of the pump light source 2, wherein the optical device 5 comprises a focusing lens 7 and a further optical element 8 for collimation and beam shaping arranged between the pump light source 2 and the gain device 4. The optical path 6 has a main axis 9.

The gain device 4 comprises a cavity (not shown) and a gain medium 10. The gain medium 10 comprises a solid state host material which is doped with rare-earth ions.

The solid state host material is selected from the following materials: (Y_{1-x-y}GdₓLu_{y})₃Al_{5-z}Ga_{z}O₁₂ (1≦z≦5; 0≦x≦1; 0≦y≦1 and x+y≦1). The rare-earth ions are Ce³⁺-ions or mixtures of Ce³⁺- and other further rare earth-ions, the further rare earth-ions selected from the group of Pr³⁺-, Sm³⁺-, Eu³⁺-, Tb³⁺-, Dy³⁺-, and Tm³⁺-ions.

The pump laser 2 is emitting blue light and/or ultraviolet light. The blue light and/or ultraviolet light emitted by the pump light source 2 is used for pumping the gain device 4 to create green laser light leaving the gain device 4. The solid state laser device 1 can be configured as a longitudinally pumped solid state laser device 1 (not shown) or a transversally pumped solid state laser device 1, wherein the laser beam 11 is aligned perpendicular to or at an angle with the main axis 9 of the optical path 6 of the pumping light. A focal spot or focal line 12 of the optical path 7 is located in the gain device 4.

FIG. 2 shows an excitation scheme of a preferred embodiment of the gain medium 10. On the left side the valence band 13 and the conduction band 14 of the solid state host material 15 is shown. On the right side two 4f-states 16, 17 and one 5d-band 18 of the Ce³⁺-ions 19 are shown. The 4f-states 16, 17 and the 5d-band 18 are energetically between the highest valence band state (upper edge of the valence band 13) and the lowest conduction band state (lower edge of the conduction band 14) of the host material 15, with the highest 4f-state 17 and the bottom edge of the 5d-band 18 having a first energy-level distance Δ1 and the lowest 4f-state 16 and the upper edge of the 5d-band 18 having a second energy-level distance Δ2, wherein the host material 15 is selected such that the resulting gain medium 10 has an energy range 20 devoid of unoccupied states for disabling excited state absorption between a lower energy 21 which is by the value of the first energy level distance Δ1 above the bottom edge of the 5d-band 18 and a higher energy 22 which is by the value of the second energy level distance Δ2 above the upper edge of the 5d-band 18. The gain medium 10 is pumped with blue light 23 emitted by the pump light source 2. The gain medium 10 absorbs the radiation of the blue light 23 via the dipole allowed 4f-5d transition (arrow 24) in the Ce³⁺-ion. From the 5d band of the Ce³⁺-ion the energy is transferred (arrow 25) to the upper lasing state of the Ce³⁺-ion (or alternatively to the further rare-earth ion) which then emits the desired laser light 26 (especially green laser light) through a transition between the upper lasing state and a lower lasing state (arrow 27). An alternative excited state absorption process (ESA process-arrow 28) cannot take place, because within the energy range 20 between the lower energy 21 and the higher energy 22 of the gain medium 10 (in this example Ce³⁺:Y₃AlGa₄O₁₂) there is no unoccupied final state for this excited state absorption process for both the exciting radiation as well as the laser light.

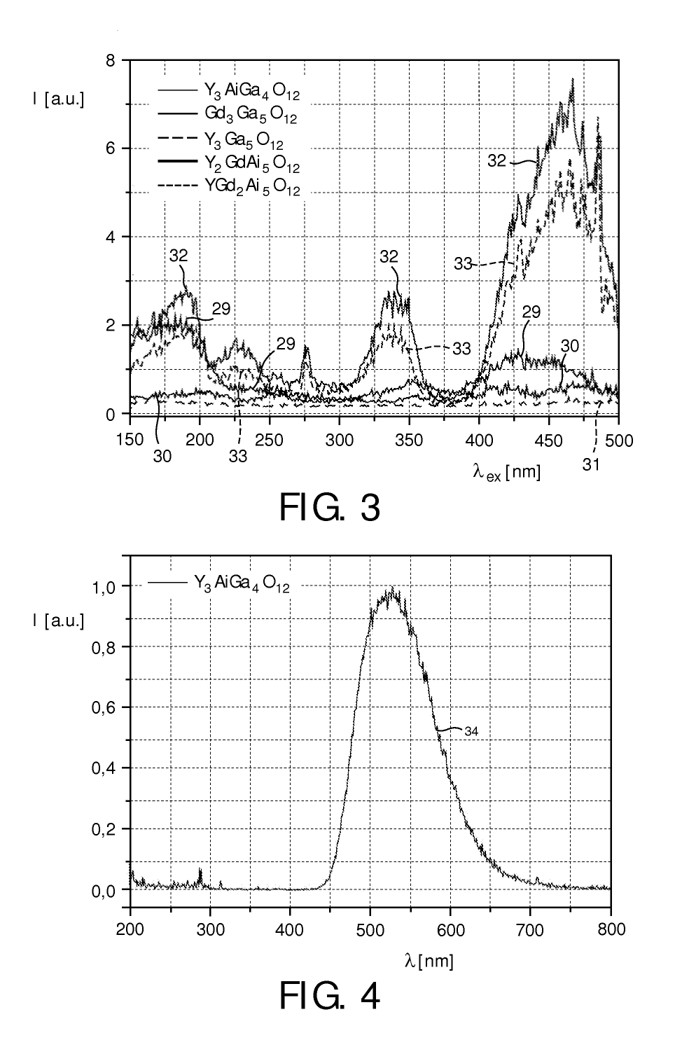

In this invention disclosure Ce³⁺:Y₃AlGa₄O₁₂ is proposed as a suitable material for blue light 23 pumped solid-state lasers 1. In FIG. 3 the excitation spectra of five different Cerium-doped gain medium host materials 15 are shown: (Ce³⁺:Y₃AlGa₄O₁₂) 29, (Ce³⁺:Gd₃Ga₅O₁₂) 30, (Ce³⁺:Y₃Ga₅O₁₂) 31, (Ce³⁺:Y₂GdAl₅O₁₂) 32 and (Ce³⁺:YGd₂Al₅O₁₂) 32.

All of these materials are garnets. From these materials Y₃Ga₅O₁₂ (YGG) and Gd₃Ga₅O₁₂ (GGG) are not usable, since they show not only very low signal in the excitation spectra, but also very weak emission in the visible wavelength range. The other three materials (Y₂GdAl₅O₁₂, YGd₂Al₅O₁₂ and Y₃AlGa₄O₁₂) show a steep structure at 200 nm, which might be due to bandgap absorption involving the lower edge of the conduction band 14 of the host material 15. Ce:Y₂GdAl₅O₁₂ and Ce:YGd₂Al₅O₁₂ exhibit a maximum between 200 and 250 nm, which can be attributed to one of the higher lying 5d-levels of Ce³⁺.

Surprisingly, this 5d-level cannot be detected for Ce:Y₃AlGa₄O₁₂. Since this is the wavelength range, where the final state for excited state absorption (ESA) at a green laser wavelength from the lowest 5d-level of the Ce³⁺ is expected, excited state absorption does not play a role in this material and lasing is possible at green wavelengths in Ce:Y₃AlGa₄O₁₂. Therefore the gain medium Ce³⁺:Y₃AlGa₄O₁₂ has a main phase of the solid state host material Y₃AlGa₄O₁₂ which is doped with Ce³⁺-ions with 4f-states 16, 17 and at least one 5d-band 18 energetically between the highest valence state and the lowest conduction state of the host material 15.

FIG. 4 shows the emission spectrum 34 of 0.2 mol % Ce-doped Y₃AlGa₄O₁₂ (Ce³⁺:Y₃AlGa₄O₁₂).

For Ce-doped Y₃AlGa₄O₁₂ both absorption and emission spectra are relatively broad. The absorption spectrum in the spectral range of interest can be deduced from the excitation spectrum 29 shown in FIG. 3, to extend from 380 to 470 nm. The emission is broad with a maximum at 520 nm and shown in the emission spectrum 34 in FIG. 4. Due to the broad absorption spectrum, no specific selection of laser diodes 3 has to be made, which will—in comparison to Pr:YLF—allow for drastically reduced cost. The broad emission spectrum 34 allows for the realization of a tunable laser or—in projection applications—to suppress disturbing speckle and interference effects.

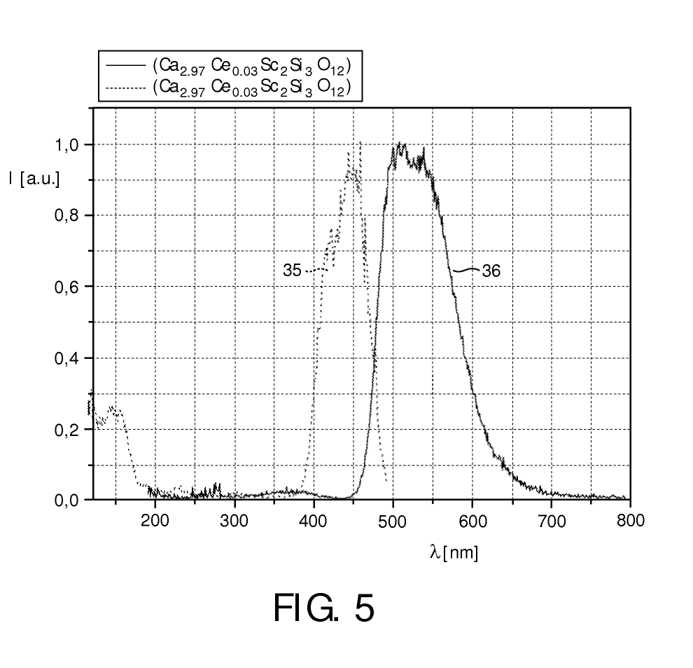

In this invention disclosure further on Ce³⁺:Ca₃Sc₂Si₃O₁₂ is proposed as another suitable material for blue light 23 pumped solid-state lasers 1. In FIG. 5 the normalized excitation spectrum (dashed line) 35 and the normalized emission spectrum (solid line) 36 of Cerium-doped gain medium host material Ca₃Sc₂Si₃O₁₂ (Ca_{2.97}Ce_{0.03}Sc₂Si₃O₁₂) is shown in the wavelength region from about 150 nm to 800 nm. The absorption spectrum in the spectral range of interest can be deduced from the excitation spectrum 35, to extend from 390 to about 520 nm. The emission spectrum 36 shows a broad structure with a maximum at 520 nm.

In this invention, the proposed material for a blue pumped solid-state laser 1 is either a crystal or a transparent polycrystalline garnet of the composition Ce³⁺:Y₃AlGa₄O₁₂ or Ce³⁺:Ca₃Sc₂Si₃O₁₂. The typical concentration of the activator Ce³⁺ is in the range of 0.005 mol % to 5 mol %, preferably 0.1 to 1 mol %. This material has been prepared by a number of different methods. The preparation involves different successive synthesis steps.

A crystal of the composition Ce³⁺:Y₃AlGa₄O₁₂ is grown from the melt by any of the known crystal grow methods like the so called Bridgman or Czochralski method. The appropriate amounts of the oxides (Y₂O₃, Al₂O₃, Ga₂O₃, CeO₂) is mixed in an inert crucible and heated in air to form a homogeneous melt of the garnet phase (T>=1750° C.). The melt is cooled down to form a crystal of the said composition, or the crystal is drawn from the melt with a seed crystal if the Czochralski method is used.

The preparation of a transparent polycrystalline ceramic body of the garnet phase with either composition of the aforementioned preferred stochiometries involves different successive synthesis steps. At first, a fine-grained powder with the appropriate garnet composition or a mixture of fine-grained oxides powders which form the garnet phase after heating is synthesized. This powder or powder mixture is pressed to form a so-called green body which is further densified by isostatic or uniaxial pressure to form a compact body of less than 50% porosity. The compact body is sintered at about 1400-1700° C. A transparent ceramic body is formed of >98% of the theoretical density. If the ceramic body shows inclusion of closed pores, these pores are removed by a post-treatment inside a hot isostatic pressing furnace.

A preferred embodiment which describes the formation of a transparent ceramic body of the composition Ce³⁺:Y₃AlGa₄O₁₂ is given below.

The powder composition is prepared by mixing e.g. high-purity oxides (>99.9%) of the cationic constituents in the correct stochiometry, and milling the mixture in an organic solvent with 1 mm alumina pearls in a ball mill to de-agglomerate the powders. A small quantity of a sintering aid (1 mol %) is added to the mill base.

A different method was also used to prepare a more homogeneous powder mixture. The cationic constituents of the desired stochiometry were dissolved in acidic medium. The dissolved cations were homogeneously precipitated by methods like oxalate process, urea process or ammonium hydrogencarbonate process, which are known to the skilled experts. These methods result in white precipitates of oxalates, hydroxides, or hydroxycarbonates. The precursor powders are dried and calcined at 600-950° C. to form a powder of the intimately mixed oxides. If the calcination temperature for the precursor mixtures is set to at about 1200° C., a phase transformation occurs and the desired cubic garnet phase Y₃AlGa₄O₁₂ is formed.

Either of the prepared powders are milled in a ball mill to de-agglomerate the aggregates which are formed during calcination. During this milling process, a sintering aid may be added. Furthermore, small amounts of an organic binder and a plasticizer (e.g. polyvinylbutyrale and glycole, respectively) are added which support the following densification step.

The milled powders are dried and pressed in a die and subsequently exposed to isostatic pressure to form compacts of the desired shape (e.g. discs of 15 mm diameter and 5 mm thickness). In another preferred method, the powder was filled in the die of a hot unaxial pressing furnace.

The pressed compacts are sintered to nearly theoretical density in vacuum or in air at a temperature of 1400-1550° C. for 3-9 hours. The powders filled in the die of a hot uniaxial pressing furnace (HUP) were pressed during sintering up to 50 MPa.

Sintering in the low temperature range of the aforementioned temperature range resulted in ceramic compacts with residual closed porosity. These compacts were further densified to nearly theoretical density inside a hot isostatic pressing furnace (HIP).

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. Solid-state laser device comprising a gain medium essentially having a main phase of a solid state host material which is doped with rare-earth ions, wherein at least a portion of the rare-earth ions are Ce³⁺-ions with at least one 4f-state and at least one 5d-band energetically between the highest valence state and the lowest conduction state of the host material, wherein
the highest 4f-state and the bottom edge of the 5d-band have a first energy-level distance and
the lowest 4f-state and the upper edge of the 5d-band have a second energy-level distance,
wherein the host material is selected such that the resulting gain medium has an energy range devoid of unoccupied states for disabling excited state absorption, the energy range is located between
a lower energy which is by the value of the first energy level distance above the bottom edge of the 5d-band and
a higher energy which is by the value of the second energy level distance above the upper edge of the 5d-band.

2. Solid-state laser device according to claim 1, wherein the 5d band is thermally isolated from the conduction band at least by 0.5 eV.

3. Solid-state laser device according to claim 1, wherein the rare-earth ions are
Ce³⁺-ions or
mixtures of Ce³⁺-ions and other rare earth-ions, the other rare earth-ions selected from the group of Pr³⁺-, Sm³⁺-, Eu³⁺-, Tb³⁺-, Dy³⁺-, and Tm³⁺-ions.

4. Solid-state laser device according to claim 1, wherein the host material comprises (Y_{1-x-y}GdₓLu_{y})₃Al_{5-z}Ga_{z}O₁₂—, wherein 1≦z≦5; 0≦x≦1; 0≦y'1 and x+y≦1.

5. Solid-state laser device according to claim 1, wherein the host material is selected to be the following material: Ca₃Sc₂Si₃O₁₂.

6. Solid-state laser device according to claim 1, wherein the host material has a dopant concentration of the rare-earth ions in the range of 0.005 mol % to 5 mol %.

7. Solid-state laser device according to claim 1, wherein the host material is a ceramic or monocrystalline material.

8. Solid-state laser device according to claim 1, further comprising a pump light source emitting blue light and/or ultraviolet light, wherein the gain medium is in an optical path of the pump light source.

9. Solid-state laser device according to claim 1, wherein the laser device is a laser device emitting green laser light.

10. Solid-state laser device according to claim 8, wherein the laser light emitted by the gain medium is aligned parallel or perpendicular to a main axis of the optical path.

11. Solid-state laser device according to claim 1, wherein the host material has an energy gap between the highest valence state and the lowest conduction state of more than 5.5 eV.

12. (canceled)

13. (canceled)

14. A lighting system according to claim 13, wherein the system is a RGB-system comprising further laser devices, wherein one of these further laser devices is emitting red light and another of the further laser devices is emitting blue light.
